(19) United States
(12) Patent Application Publication
(10) Pub. No.: US 2010/0012943 A1
(43) Pub. Date: Jan. 21, 2010

(54) THIN FILM TRANSISTOR AND MANUFACTURING METHOD THEREOF

(75) Inventors: Seung-Kyu Park, Hwaseong-si (KR); Kunal Satyabhushan Girotra, Mountain View, CA (US); Jong-Moo Huh, Hwaseong-si (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/429,125

(22) Filed: Apr. 23, 2009

(30) Foreign Application Priority Data
Jul. 18, 2008 (KR) 10-2008-0070239

(51) Int. Cl. H01L 29/786; H01L 21/336

(52) U.S. Cl. 257/66; 438/157; 257/40; 257/72; 257/E21.411; 257/E29.273

(57) ABSTRACT

The present invention relates to a thin film transistor and a manufacturing method thereof. A thin film transistor according to an exemplary embodiment of the present invention includes: a first electrode arranged on a substrate; a second electrode arranged on the substrate and separated from the first electrode; a first ohmic contact arranged on an upper surface of the first electrode; a second ohmic contact arranged on an upper surface of the second electrode; a first buffer member covering a lateral surface of the first electrode and the second electrode; a semiconductor member contacted with an upper surface of the first buffer member, and the first ohmic contact and the second ohmic contact; an insulating layer arranged on the semiconductor member; and a third electrode arranged on the insulating layer, and disposed on the semiconductor member.

### CROSS-REFERENCE TO RELATED APPLICATION

This application claims priority from and the benefit of Korean Patent Application No. 10-2008-0070239, filed on Jul. 18, 2008, which is hereby incorporated by reference for all purposes as if fully set forth herein.

### BACKGROUND OF THE INVENTION

1. Field of the Invention

The present invention relates to a thin film transistor and a manufacturing method thereof.

2. Discussion of the Background

An active matrix flat panel display may include a plurality of pixels for displaying images, and may display the images by controlling pixel luminance according to given information.

An active matrix flat panel display pixel includes a transistor for applying a driving signal to the pixel. The transistor is made of a thin film transistor (TFT), and the thin film transistor may be divided into a poly-crystalline silicon thin film transistor and an amorphous silicon thin film transistor according to the kind of active layer.

In the case of the polysilicon thin film transistor, the polysilicon layer may be disposed with the lowest layer, an ohmic contact layer and an electrode are formed thereon, and then a gate insulating layer and a gate electrode are formed thereon.

However, the surface of the channel region in the polysilicon layer is easily penetrated with an impurity and damaged in the following process or the crystallization process.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides a thin film transistor and manufacturing method thereof that may reduce damage to the thin film transistor channel region and penetration of an impurity.

Additional features of the invention will be set forth in the description which follows, and in part will be apparent from the description, or may be learned by practice of the invention.

The present invention discloses a thin film transistor that includes: a first electrode arranged on a substrate; a second electrode arranged on the substrate and separated from the first electrode; a first ohmic contact arranged on an upper surface of the first electrode; a second ohmic contact arranged on an upper surface of the second electrode; a first buffer member covering a lateral surface of the first electrode and a lateral surface of the second electrode; a semiconductor member contacted with an upper surface of the first buffer member and the first ohmic contact and the second ohmic contact; an insulating layer arranged on the semiconductor member; and a third electrode arranged on the insulating layer and on the semiconductor member.

The present invention also discloses a thin film transistor manufacturing method that includes: forming a first electrode and a second electrode on a substrate; respectively forming a first ohmic contact and a second ohmic contact on an upper surface of the first electrode and an upper surface of the second electrode; forming a buffer member on the first ohmic contact, the second ohmic contact, and the substrate; forming a semiconductor member on the buffer member, the first ohmic contact, and the second ohmic contact; forming an insulating layer on the semiconductor member; and forming a third electrode on the insulating layer.

The present invention also discloses an organic light emitting device including: an organic light emitting element to emit light according to a driving current; a driving transistor connected to the organic light emitting element to flow the driving current according to a data signal; an insulating layer arranged on a semiconductor member; and a third electrode arranged on the insulating layer and disposed on the semiconductor member. A switching transistor transmits the data signal to the driving transistor. The driving transistor includes a first electrode arranged on a substrate, a second electrode arranged on the substrate and separated from the first electrode, a first ohmic contact arranged on an upper surface of the first electrode, a second ohmic contact arranged on an upper surface of the second electrode, a first buffer member covering a lateral surface of the first electrode and a lateral surface of the second electrode, and the semiconductor member contacted with an upper surface of the first buffer member, the first ohmic contact, and the second ohmic contact.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a thin film transistor according to an exemplary embodiment of the present invention.

FIG. 2, FIG. 3, and FIG. 4 are cross-sectional views of intermediate steps in a manufacturing method of the thin film transistor shown in FIG. 1 according to an exemplary embodiment of the present invention.

FIG. 5 is a view showing measurement positions of the characteristics after manufacturing a plurality of thin film transistors on a substrate according to an exemplary embodiment of the present invention.

FIG. 6 is a characteristic curve of the thin film transistor shown in FIG. 1.

FIG. 7 is a characteristic curve of a thin film transistor without a buffer member.

FIG. 8 is an equivalent circuit diagram of an organic light emitting device according to an exemplary embodiment of the present invention.

FIG. 9 is a layout view of an organic light emitting device according to an exemplary embodiment of the present invention.

FIG. 10 is a cross-sectional view of the organic light emitting device shown in FIG. 9 taken along line X-X.

FIG. 11 is a layout view of an organic light emitting device according to another exemplary embodiment of the present invention.

FIG. 12 is a cross-sectional view of the organic light emitting device of FIG. 1 taken along line XII-XII.

FIG. 13, FIG. 15, FIG. 17, FIG. 19, and FIG. 21 are layout views of intermediate steps in the manufacturing method of the organic light emitting device shown in FIG. 9 and FIG. 10 according to an exemplary embodiment of the present invention.

FIG. 14 is a cross-sectional view of the organic light emitting device of FIG. 13 taken along line XIV-XIV.

FIG. 16 is a cross-sectional view of the organic light emitting device of FIG. 15 taken along line XVI-XVI.

FIG. 18 is a cross-sectional view of the organic light emitting device of FIG. 17 taken along line XVIII-XVIII.

FIG. 20 is a cross-sectional view of the organic light emitting device of FIG. 19 taken along line XX-XX.

FIG. 22 is a cross-sectional view of the organic light emitting device of FIG. 21 taken along line XXII-XXII.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

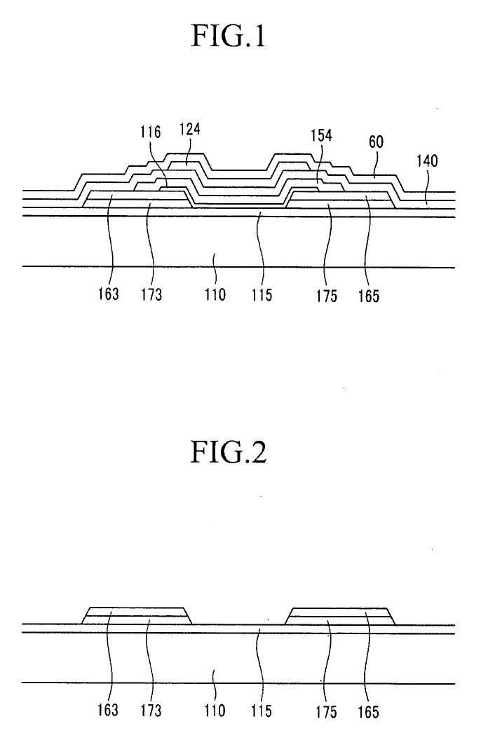

A thin film transistor according to an exemplary embodiment of the present invention will be described with reference to FIG. 1.

A buffer layer 115, which may be made of an insulating material such as silicon oxide (SiOx) or silicon nitride (SiNx), is formed on an insulation substrate 110, which may be made of transparent glass or plastic.

An input electrode 173 and an output electrode 175, which are separated, are formed on the buffer layer 115. The input electrode 173 and the output electrode 175 may be formed of a refractory metal such as molybdenum, chromium, tantalum, or titanium, or an alloy thereof, and may have a multi-film structure including a refractory metal film (not shown) and a low resistance conductive layer (not shown). Examples of the multi-layered structure include a double-layered structure of a chromium (alloy) lower layer and an aluminum (alloy) upper layer, and an aluminum (alloy) lower layer and a molybdenum (alloy) upper layer, as well as a triple-layered structure of a molybdenum (alloy) lower layer, an aluminum (alloy) intermediate layer, and a molybdenum (alloy) upper layer. However, the input electrode 173 and the output electrode 175 may be made of various other metals or conductors.

A first ohmic contact 163 and a second ohmic contact 165 are respectively formed on the input electrode 173 and the output electrode 175.

The first ohmic contact 163 and the second ohmic contact 165 do not cover the lateral surface of the input electrode 173 and the output electrode 175, particularly the lateral surfaces that are opposite to each other. In FIG. 1, the first ohmic contact 163 and the second ohmic contact 165 have the same plane shape as the input electrode 173 and the output electrode 175, respectively.

The first ohmic contact 163 and the second ohmic contact 165 may be made of a crystalline semiconductor such as n+ polysilicon (polycrystalline silicon) that is doped with an n-type impurity at a high concentration.

The corresponding lateral surfaces of the input electrode 173 and the output electrode 175 are covered by a buffer member 116. As shown in FIG. 1, the buffer member 116 may cover a portion of the upper surface of the first ohmic contact 163 and the second ohmic contact 165, as well as a portion of the buffer layer 115 between the input electrode 173 and the output electrode 175. That is, the buffer member 116 may cover a path from the portion of the upper surface of the first ohmic contact 163 to the portion of the upper surface of the second ohmic contact 165. The buffer member 116 may be made of an insulating material such as silicon oxide (SiOx) or silicon nitride (SiNx).

A semiconductor member 154 is formed on the first ohmic contact 163 and the second ohmic contact 165, with the buffer member 116 therebetween. The semiconductor member 154 contacts the upper surface of the first and second ohmic contacts 163 and 165, and is connected to the input electrode 173 and the output electrode 175 through the first ohmic contacts 163 and the second ohmic contact 165, respectively. However, the semiconductor member 154 does not directly contact the input electrode 173 and the output electrode 175, and also does not directly contact the buffer layer 115 between the input electrode 173 and the output electrode 175. This is because the buffer member 116 covers the entire surface from the portion of the upper surface of the first ohmic contact 163 to the portion of the surface of the second ohmic contact 165.

The semiconductor member 154 may be made of microcrystalline silicon, which has a grain diameter of less than 10 μm, and if the grain diameter is larger than 10 μm, the semiconductor may be made of polysilicon.

A gate insulating layer 140, which may be made of silicon nitride or silicon oxide, is formed on the semiconductor member 154. As shown in FIG. 1, the gate insulating layer 140 may cover the exposed portion of the upper part of the first ohmic contact 163 and the second ohmic contact 165, and exposed lateral surfaces of the input electrode 173 and the output electrode 175.

A control electrode 124 is formed on the gate insulating layer 140. The control electrode 124 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, nitrides thereof, or chromium (Cr), tantalum (Ta), titanium (Ti), or the like. An insulating layer 60 is formed on the control electrode 124.

When the thin film transistor is turned on, a current is passed from the input electrode 173, through the first ohmic contact 163 and the semiconductor member 154, and flows to the output electrode 175 through the second ohmic contact 165. The ohmic contacts 163 and 165 are disposed between the semiconductor member 154 and the underlying input electrode 173 and output electrode 175, thereby reducing contact resistance therebetween.

However, if the input electrode 173 and the output electrode 175 directly contact the semiconductor member 154 without the first ohmic contact 163 and the second ohmic contact 165, the contact resistance is increased and the on-current characteristics may be deteriorated. In the present exemplary embodiment, the buffer member 116 is disposed on the path where the semiconductor member 154, and the input electrode 173 and the output electrode 175 may otherwise contact each other, thereby preventing the direct contact. Particularly, the buffer member 116 covers the exposed lateral surfaces of the input electrode 173 and the output electrode 175 to prevent direct contact with the semiconductor member 154.

In the present exemplary embodiment, the first ohmic contact 163 and the second ohmic contact 165 are not formed on the lateral surfaces of the input electrode 173 and the output electrode 175, respectively. Therefore, when turning on the thin film transistor, the current path is formed through the upper surface of the input electrode 173 and the output electrode 175. When the first ohmic contact 163 and the second ohmic contact 165 are only formed on the upper surface of the input electrode 173 and the output electrode 175, respectively, the thickness thereof is relatively uniform. However when the first ohmic contact 163 and the second ohmic contact 165 are formed on the lateral surfaces of the input electrode 173 and the output electrode 175, respectively, the thickness of the ohmic contacts 163 and 165 on the lateral surfaces may not be uniform. If the thickness of the portion of the ohmic contacts 163 and 165 disposed on the current path is not uniform, the characteristics of the thin film transistor may deteriorate. Accordingly, in the present exemplary embodiment, the first ohmic contact 163 and second ohmic contact 165 are only formed on the upper surface of the input electrode 173 and the output electrode 175, respectively, such that the current always flows through the upper surface of the input electrode 173 and the output electrode 175 when the thin film transistor is turned on.

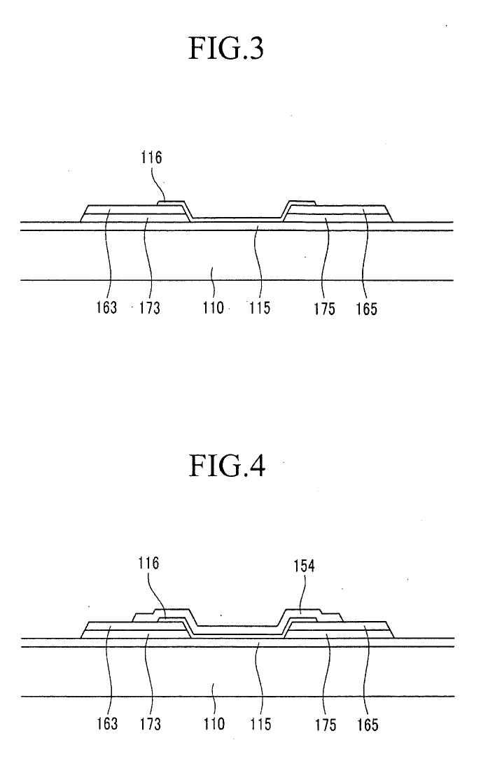

Next, a method of manufacturing the thin film transistor shown in FIG. 1 will be described in detail with reference to FIG. 2, FIG. 3, and FIG. 4.

FIG. 2, FIG. 3, and FIG. 4 are cross-sectional views of intermediate steps in a method of manufacturing the thin film transistor shown in FIG. 1 according to an exemplary embodiment of the present invention.

Referring to FIG. 2, a buffer layer 115, a conductor layer, and an impurity semiconductor layer are sequentially deposited on a substrate 110. The buffer layer 115 may be made of silicon oxide or silicon nitride, and may have a thickness of about 5000 Å. The impurity semiconductor layer may be made of amorphous silicon doped with an N-type impurity at a high concentration, and have a thickness of about 300 Å to 2000 Å.

Next, the impurity semiconductor layer may be crystallized by field-enhanced rapid thermal annealing (FE-RTA).

A photosensitive film (not shown) is formed on the impurity semiconductor layer, and the impurity semiconductor layer and the conductor are etched using the photosensitive film as a mask to form a first ohmic contact 163, a second ohmic contact 165, an input electrode 173, and an output electrode 175. In this way, the first ohmic contact 163, the second ohmic contact 165, the input electrode 173, and the output electrode 175 are made through one photolithography step such that the manufacturing process may be simplified and the plane shapes thereof may be the same. Also, the conductor layer and the impurity semiconductor layer are sequentially deposited before patterning such that the first ohmic contact 163 and the second ohmic contact 165 only exist on the upper surface of the input electrode 173 and the output electrode 175, respectively, and the lateral surface of the input electrode 173 and the output electrode 175 are exposed.

The impurity semiconductor layer may be dry-etched and the conductor layer may be wet-etched, but they both may be dry-etched or wet-etched.

When dry-etching the impurity semiconductor layer, a gas such as O₂ may be used, however the exposed surface of the buffer layer 115 may be contaminated or damaged by the gas.

When dry-etching the impurity semiconductor layer and wet-etching the conductor layer, the underlying conductor layer may be over-etched such that the first ohmic contact 163 and the second ohmic contact 165 may abruptly protrude on the front of the input electrode 173 and the output electrode 175. Thus, the profile of the layers that are deposited in the following process may be deteriorated.

Referring to FIG. 3, an insulating layer made of silicon oxide or silicon nitride is deposited and patterned to form a buffer member 116. As above-described, the buffer member 116 may cover the path from the upper surface of the first ohmic contact 163 to the upper surface of the second ohmic contact 165.

Accordingly, because the buffer member 116 covers all portions of the buffer layer 115 from the input electrode 173 to the output electrode 175, it is immaterial whether the corresponding portion is contaminated or damaged in the previous etching step of the impurity semiconductor layer. Also, the buffer member 116 covers all the paths from the buffer layer 115 between the input electrode 173 and the output electrode 175 to the upper surface of the first ohmic contact 163 and the second ohmic contact 165 such that deterioration of the surface profile formed by the first ohmic contact 163 and the second ohmic contact 165 is reduced, and thereby the profile of the layers that are formed in the following process may be improved.

The buffer member 116 may be wet-etched, which reduces the damage to the first ohmic contact 163 and the second ohmic contact 165 compared with dry-etching.

Referring to FIG. 4, a microcrystalline silicon layer is deposited with a thickness of about 50 Å to 2000 Å by chemical vapor deposition (CVD). Next, a photosensitive film is formed on the microcrystalline silicon layer, is exposed and developed, and the microcrystalline silicon layer is dry-etched by using the photosensitive film as a mask to form a semiconductor member 154.

When the ohmic contacts 163 and 165 are polysilicon, it may be easy to form the microcrystalline silicon layer, and the contact characteristics may be good. Also, the microcrystalline silicon layer may be formed by chemical vapor deposition at a low temperature such that deformation of the substrate 110 due to heat treatment and increasing microcrystalline silicon layer defects due to hydrogen secession may not be generated.

Also, the microcrystalline silicon layer may be formed after completing the crystallization of the ohmic contacts 163 and 165 such that impurities may not be diffused into the microcrystalline silicon layer.

Finally, referring to FIG. 1, the gate insulating layer 140 is deposited, and a control electrode 124 is formed.

To evaluate the characteristics of the thin film transistor shown in FIG. 1, a thin film transistor was manufactured without the buffer member 116 of FIG. 1. If the buffer member 116 is omitted, the lateral surfaces of the input electrode 173 and the output electrode 175 may directly contact the semiconductor member 154. To prevent this, a thin film transistor may be designed so that the first ohmic contact 163 and the second ohmic contact 165 cover the lateral surface of the input electrode 173 and the output electrode 175, respectively. To this end, the input electrode 173 and the output electrode 175 are formed, and then the first ohmic contact 163 and the second ohmic contact 165 are formed, with a larger size than the input electrode 173 and the output electrode 175, by using a separate mask.

A plurality of thin film transistors may be formed on one substrate, and a plurality of thin film transistors as in FIG. 1 may be formed on another substrate. The area of the substrate is wide such that a division exposure method is applied in which the substrate is divided into a plurality of regions and exposed per region under the photo process.

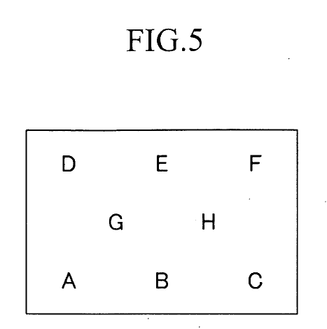

Next, the current Ids is measured between the source-drain, that is, the input electrode and the output electrode, according to the voltage between the gate-source of the thin film transistor, that is, the voltage Vgs between the control electrode and the input and output electrodes, in the eight positions A-H on the substrate, as shown in FIG. 5.

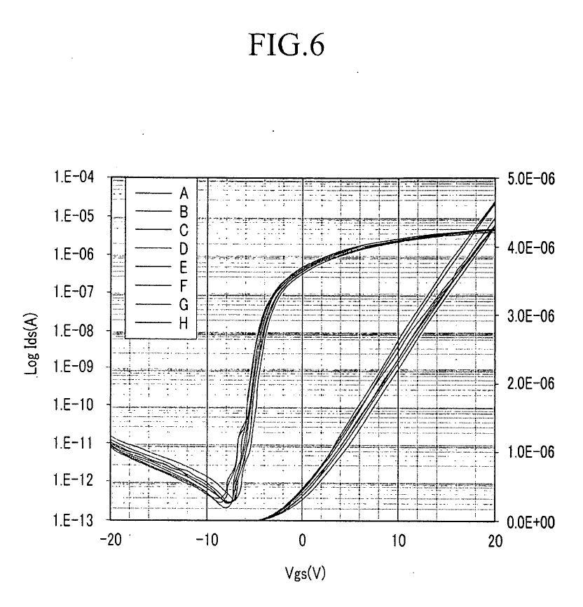

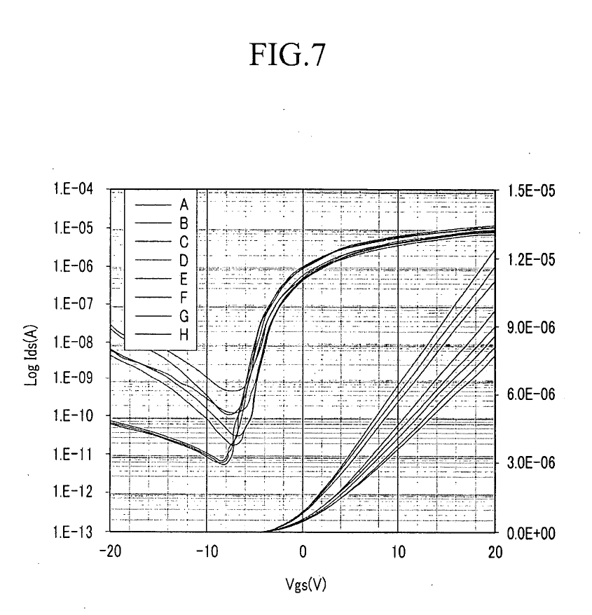

FIG. 6 is a characteristic curve of the thin film transistor shown in FIG. 1, and FIG. 7 is a characteristic curve of a thin film transistor without a buffer member. In FIG. 6 and FIG. 7, a vertical axis represents the current Ids between the input electrode and the output electrode on a logarithmic scale.

As shown in FIG. 6 and FIG. 7, the curved lines represent even distributions in the several positions in the case that the buffer member exists in the thin film transistor. However, the curved lines are not uniform in the case that the buffer member does not exist in the thin film transistor. Thus, FIG. 6 and FIG. 7 show that the characteristics of the thin film transistor without the buffer member are more uneven than those of the film transistor including the buffer member.

Also, FIG. 6 and FIG. 7 show that the off-current of the thin film transistor including the buffer member is lower than the off-current of the thin film transistor without the buffer member.

This results because the alignment degree between the input electrode 173 and the output electrode 175, and the first ohmic contact 163 and the second ohmic contact 165, are different according to the exposure regions when forming the thin film transistor without the buffer member 116.

If the buffer member 116 is omitted, the first ohmic contact 163 and the second ohmic contact 165 covers the lateral surfaces of the input electrode 173 and the output electrode 175, respectively, and the semiconductor member 154 is formed thereon. When the thin film transistor is turned on, the current path passes through the corresponding lateral surfaces of the input electrode 173 and the output electrode 175, and the portion of the first ohmic contact 163 and second ohmic contact 165 that are respectively deposited on the lateral surfaces.

The shortest distance from the corresponding lateral surface of the input electrode 173 and the output electrode 175 to the semiconductor member 154, that is, the thickness of the portion of the first ohmic contact 163 and the second ohmic contact 165 that is deposited on the respective lateral surface of the input electrode 173 and the output electrode 175, is changed according to the alignment degree between the input electrode 173 and the output electrode 175, and the first ohmic contact 163 and the second ohmic contact 165, respectively.

For example, if the first and second ohmic contacts 163 and 165 are correctly aligned, the thickness of the first ohmic contact 163 and the second ohmic contact 165 that are deposited on the lateral surfaces of the input electrodes 173 and the output electrode 175, respectively, are the same. However, if the first and second ohmic contacts 163 and 165 slightly lean to the left side, the thickness of the first ohmic contact 163 and the second ohmic contact 165 that are deposited on the left lateral surface of the input electrode 173 and the output electrode 175, respectively, is thicker than the thickness of the ohmic contacts 163 and 165 that are deposited on the right lateral surface. In contrast, if the first and second ohmic contacts 163 and 165 slightly lean to the right side, the thickness of the first ohmic contact 163 and second ohmic contact 165 that are deposited on the right lateral surface of the input electrode 173 and the output electrode 175, respectively, is thicker than the thickness of the ohmic contacts 163 and 165 that are deposited on the left lateral surface.

This thickness difference may generate a current path and influence the characteristics of the thin film transistor. Thus, as above-described, the alignment degree between the input electrode 173 and the output electrode 175, and the first ohmic contact 163 and the second ohmic contact 165, respectively, is different for every exposure region such that the characteristics of the thin film transistor are changed in every region.

Also, when a misalignment is severely generated, the first ohmic contact 163 and the second ohmic contact 165 may not cover the input electrode 173 and the output electrode 175, respectively, and thus the semiconductor member 154 may directly contact the input electrode 173 and the output electrode 175 such that the off-current of the thin film transistor is increased.

When forming the thin film transistor without the buffer member 116, the surface of the buffer layer 115 between the input electrode 173 and the output electrode 175 may be contaminated or damaged in the dry-etching process for forming the ohmic contacts 163 and 165, and may directly contact the semiconductor member 154 such that the characteristics of the semiconductor member 154 are deteriorated. Particularly, it has been shown that oxygen gas O₂ used in the dry-etching process remains in the surface of the buffer layer 115 and negatively influences the microcrystalline silicone of the semiconductor member 154. As shown in FIG. 1, the buffer member 116 covers all portions of the buffer layer 115 from the input electrode 173 to the output electrode 175 such that the semiconductor member 154 does not contact the buffer layer 115 in the corresponding region.

There may also be an uneven profile of the lower surface of the semiconductor member 154. As shown in FIG. 1, the buffer member 116 causes a gentle profile of the surface under the semiconductor member 154. However this is not the case in a thin film transistor without the buffer member 116, such that the profile of the semiconductor member 154 may be poor, and thereby obstacles may be generated in the current path.

The thin film transistor of the present exemplary embodiment may be applied to a flat panel display such as an organic light emitting device or a liquid crystal display.

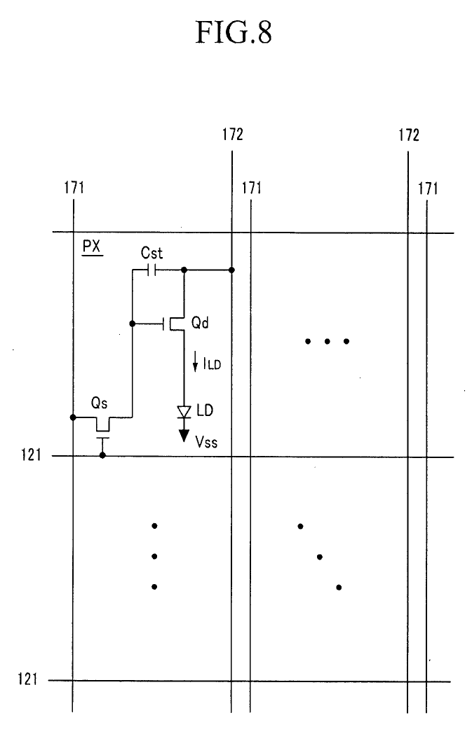

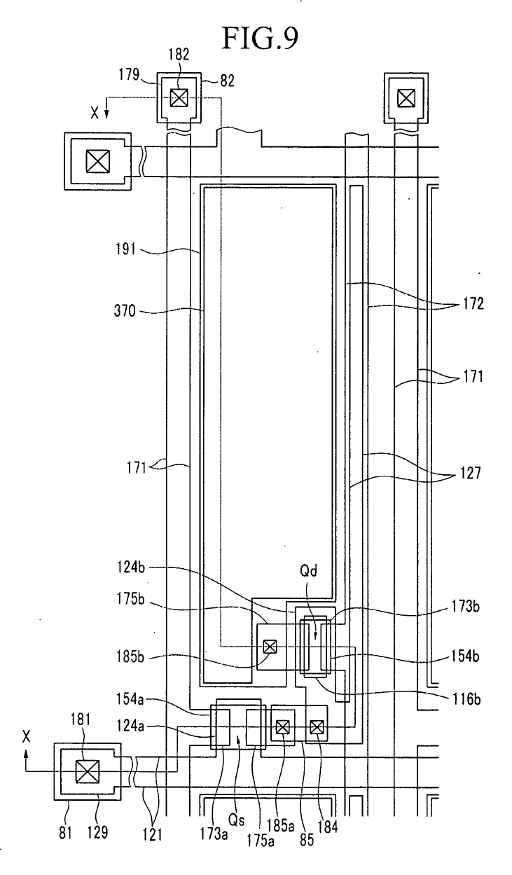

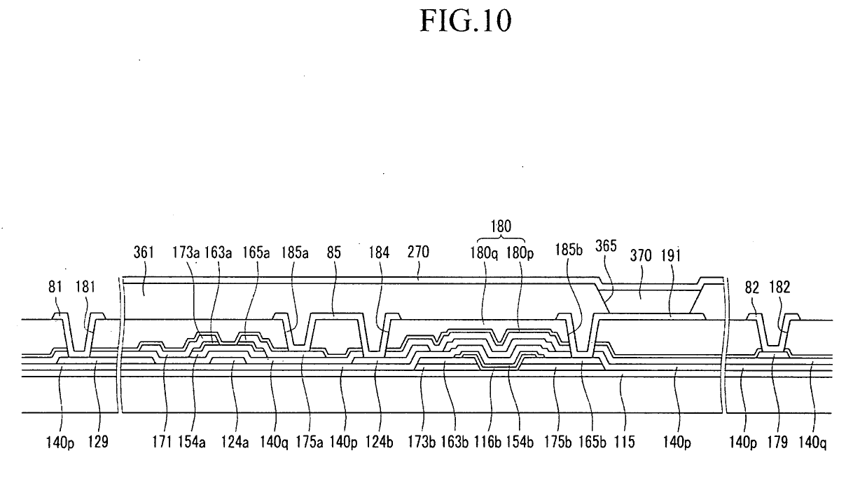

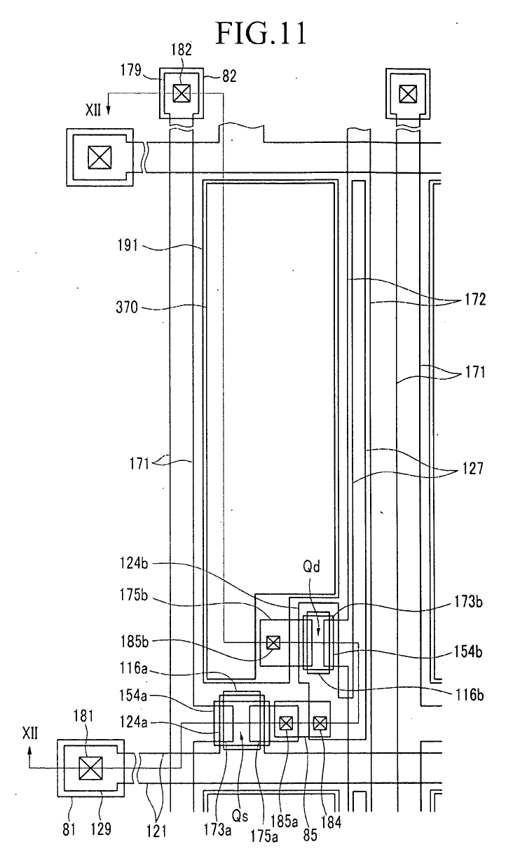

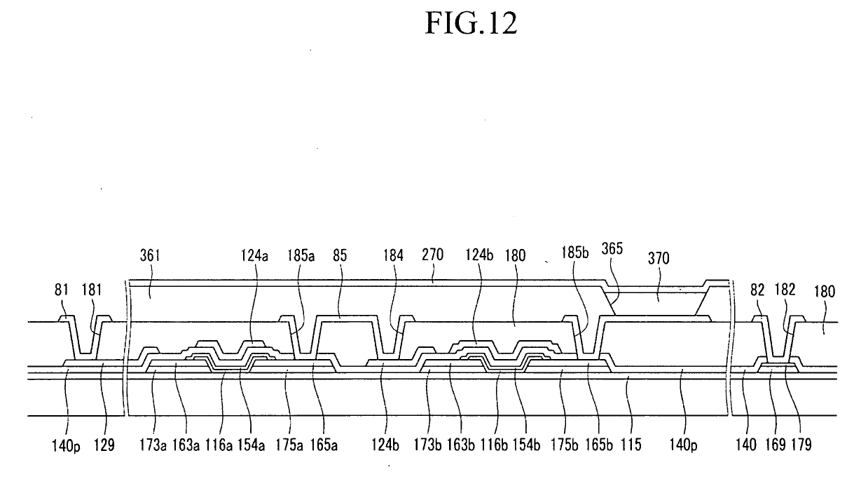

Next, an organic light emitting device including the thin film transistor shown in FIG. 1 will be described with reference to FIG. 8, FIG. 9, FIG. 10, FIG. 11, and FIG. 12.

FIG. 8 is an equivalent circuit diagram of an organic light emitting device according to an exemplary embodiment of the present invention.

Referring to FIG. 8, an organic light emitting device according to the present exemplary embodiment includes a plurality of signal lines 121, 171, and 172, and a plurality of pixels PX connected thereto and arranged substantially in a matrix.

The signal lines include a plurality of gate lines 121 for transmitting gate signals (or scanning signals), a plurality of data lines 171 for transmitting data signals, and a plurality of driving voltage lines 172 for transmitting a driving voltage. The gate lines 121 extend substantially in a row direction and substantially parallel to each other, and the data lines 171 and the driving voltage lines 172 extend substantially in a column direction and substantially parallel to each other.

Each pixel PX includes a switching transistor Qs, a driving transistor Qd, a capacitor Cst, and an organic light emitting element LD.

The switching transistor Qs has a control terminal connected to one of the gate lines 121, an input terminal connected to one of the data lines 171, and an output terminal connected to the driving transistor Qd. The switching transistor Qs transmits the data signals applied to the data line 171 to the driving transistor Qd in response to a gate signal applied to the gate line 121.

The driving transistor Qd has a control terminal connected to the switching transistor Qs, an input terminal connected to the driving voltage line 172, and an output terminal connected to the organic light emitting element. The driving transistor Qd drives an output current ILD having a magnitude depending on the voltage between the control terminal and the input terminal thereof.

The capacitor Cst is connected between the control terminal and the input terminal of the driving transistor Qd. The capacitor Cst stores a data signal applied to the control terminal of the driving transistor Qd and maintains the data signal after the switching transistor Qs turns off.

The organic light emitting element LD as an organic light emitting diode (OLED) has an anode connected to the output terminal of the driving transistor Qd and a cathode connected to a common voltage Vss. The organic light emitting element LD emits light having an intensity depending on an output current ILD of the driving transistor Qd, thereby displaying images.

The switching transistor Qs and the driving transistor Qd are n-channel field effect transistors (FETs), and at least one among them may have the structure shown in FIG. 1. However, at least one of the switching transistor Qs and the driving transistor Qd may be a p-channel FET. In addition, the connections among the transistors Qs and Qd, the capacitor Cst, and the organic light emitting diode LD may be modified.

Next, the detailed structure of the organic light emitting device shown in FIG. 8 will be described with reference to FIG. 9, FIG. 10, FIG. 11, and FIG. 12, as well as FIG. 8.

FIG. 9 is a layout view of an organic light emitting device according to an exemplary embodiment of the present invention, FIG. 10 is a cross-sectional view of the organic light emitting device shown in FIG. 9 taken along the line X-X, FIG. 11 is a layout view of an organic light emitting device according to another exemplary embodiment of the present invention, and FIG. 12 is a cross-sectional view of the organic light emitting device of FIG. 11 taken along line XII-XII.

The following description will be focused on an organic light emitting device of FIG. 9 and FIG. 10, and in the description of an organic light emitting device of FIG. 11 and FIG. 12, only parts that are different from the organic light emitting device of FIG. 9 and FIG. 10 will be described.

A buffer layer 115 made of silicon oxide (SiOx) is formed on an insulation substrate 110 that is made of transparent glass or plastic.

A driving voltage line 172 and a first output electrode 175b are formed on the buffer layer 115.

The driving voltage line 172 transmits a driving voltage and extends substantially in a longitudinal direction. The driving voltage line 172 includes a first input electrode 173b extending sideways.

The first output electrode 175b is separated from the driving voltage line 172, and is paired with and opposite to the first input electrode 173b.

An ohmic contact stripe 163b is formed on the driving voltage line 172, and an ohmic contact island 165b is formed on the first output electrode 175b.

The ohmic contact stripe 163b has substantially the same plane shape as the driving voltage line 172, and includes a protrusion disposed on the first input electrode 173b. The ohmic contact island 165b has substantially the same plane shape as the first output electrode 175b.

A buffer member 116b is formed on the ohmic contacts 163b and 165b and the exposed portion of the buffer layer 115 therebetween. The buffer member 116b may cover the path from the portion of the upper surface of the protrusion of the ohmic contact stripe 163b to the portion of the upper surface of the ohmic contact island 165b.

A first semiconductor island 154b is formed on the protrusion of the ohmic contact stripe 163b, the ohmic contact island 165b, and the buffer member 116b therebetween. The first semiconductor island 154b may be made of microcrystalline silicon.

A gate insulating layer 140p made of silicon nitride or silicon oxide is formed on the first semiconductor island 154b and the ohmic contacts 163b and 165b.

A plurality of first control electrodes 124b and a plurality of gate lines 121 are formed on the first gate insulating layer 140p.

The first control electrode 124b is disposed on the first semiconductor island 154b and includes a plurality of storage electrodes 127 overlapping the driving voltage line 172 to form the storage capacitor Cst.

The gate line 121 transmits a gate signal, and extends in a transverse direction, thereby crossing the driving voltage line 172. Each gate line 121 includes a second control electrode 124a extending upward and a wide end portion 129 to connect to another layer or an external driving circuit. The gate lines 121 may be directly connected to the gate driver (not shown) that generates the gate signal, and the gate driver may be directly integrated with the substrate 110.

A second gate insulating layer 140q made of silicon oxide or silicon nitride is formed on the first control electrode 124b and the gate line 121.

A plurality of second semiconductor islands 154a made of hydrogenated amorphous silicon are formed on the second gate insulating layer 140q. The second semiconductor islands 154a are disposed on the second control electrodes 124a.

A plurality of a pair of ohmic contacts 163a and 165a are formed on the second semiconductor islands 154a. The ohmic contacts 163a and 165a have an island shape, and may be made of a material such as n+ hydrogenated amorphous silicon in which an n-type impurity such as phosphorus is doped with a high concentration.

A plurality of data lines 171 and a plurality of second output electrodes 175a are formed on the ohmic contacts 163a and 165a, respectively, and the second gate insulating layer 140q.

The data lines 171 transmit data voltages, and extend substantially in the longitudinal direction while crossing the gate lines 121. Each data line 171 includes a plurality of second input electrodes 173a extending toward the second control electrodes 124a and having a “U” shape, and a wide end portion 179 to connect to other layers or an external driving circuit. The data lines 171 may extend and directly connect to a data driver (not shown) that generates a data signal, and the data driver may be directly integrated with the substrate 110.

The second output electrodes 175a are separated from the data lines 171. The second input electrodes 173a and the second output electrodes 175a are opposite to each other with reference to the second control electrodes 124a.

The data lines 171 and the second output electrodes 175a may be made of the same material as the driving voltage line 172.

The ohmic contacts 163a and 165a are interposed only between the underlying semiconductor islands 154a and the overlying data lines 171 and second output electrodes 175a, respectively, and reduce contact resistance therebetween. The second semiconductor islands 154a include a portion between the second input electrodes 173a and the second output electrodes 175a, and portions situated beneath the second input electrodes 173a and the second output electrodes 175a.

A passivation layer 180 is formed on the data lines 171, the second output electrodes 175a, and the exposed second semiconductor islands 154a. The passivation layer 180 includes a lower layer 180p made of an inorganic insulator such as silicon nitride or silicon oxide, and an upper layer 180q made of an organic insulator. It is preferable that the organic insulator has a dielectric constant of less than 4.0, and photosensitivity, and it may provide a flat surface. Alternatively, the passivation layer 180 may be a single-layered structure made of an inorganic insulator or an organic insulator.

The passivation layer 180 has a plurality of contact holes 182 and 185a respectively exposing the end portions 179 of the data lines 171 and the second output electrodes 175a. The passivation layer 180 and the second gate insulating layer 140q have a plurality of contact holes 184 and 181 respectively exposing the first control electrodes 124b and the end portions 129 of the gate line 121. The passivation layer 180 and the first and second gate insulating layers 140p and 140q have a plurality of contact holes 185b exposing the ohmic contact island 165b.

A plurality of pixel electrodes 191, a plurality of connecting members 85, and a plurality of contact assistants 81 and 82 are formed on the passivation layer 180. They are preferably made of a transparent conductor such as ITO or IZO, or a reflective conductor such as silver, aluminum, chromium, or alloys thereof.

The pixel electrodes 191 are connected to the first output electrode 175b through the contact holes 185b, and the connecting members 85 connect the first control electrodes 124b and the second output electrodes 175a to each other through the contact holes 184 and 185a.

The contact assistants 81 and 82 are respectively connected to the end portions 129 and 179 of the gate lines 121 and the data lines 171 through the contact holes 181 and 182. The contact assistants 81 and 82 adhere the end portions 129 and 179 of the gate lines 121 and the data lines 171, respectively, to outside components, and protect them.

A partition 361 is formed on the passivation layer 180. The partition 361 surrounds the edges of the pixel electrodes 191 like a bank to define a plurality of openings 365 exposing the pixel electrodes 191, and is made of an organic insulator or an inorganic insulator. The partition 361 may be made of a photosensitive material including a black pigment, and because the partition 361 functions as a light blocking member, the manufacturing process may be simplified in this case.

An organic light emitting member 370 is formed in the openings 365 defined by the partition 361 on the pixel electrodes 191. The organic light emitting member 370 may be made of an organic material uniquely emitting light of one primary color such as red, green, or blue. The organic light emitting device displays desired images by spatially combining the colored light of the primary colors emitted by the organic light emitting members 370. However, the organic light emitting member 370 may emit white light, and the organic light emitting member 370 may have a structure in which a plurality of organic material layers for emitting different color light are deposited in this case. In this case, a plurality of color filters (not shown) may be provided on or under the organic light emitting member 370.

The organic light emitting member 370 may have a multi-layered structure including the emission layer (not shown) and an auxiliary layer (not shown) for improving efficiency of light emission of the emitting layer. The auxiliary layer may include a hole transport layer and an electron transport layer for controlling the balance of electrons and holes, and an electron injection layer and a hole injection layer for enhancing the injection of electrons and holes.

A common electrode 270 is formed on the organic light emitting member 370. The common electrode 270 receives a common voltage Vss, and may be made of a reflective metal or their alloy, such as calcium (Ca), barium (Ba), magnesium (Mg), silver (Ag), aluminum (Al), etc.

In this organic light emitting device, a pixel electrode 191, an organic light emitting member 370, and the common electrode 270 form an organic light emitting element LD having the pixel electrode 191 as an anode and the common electrode 270 as a cathode, or vice versa.

Also, the second control electrode 124a connected to the gate line 121, the second input electrode 173a connected to the data line 171, and the second output electrode 175a form a switching thin film transistor Qs along with the second semiconductor island 154a, and the channel of the switching thin film transistor Qs is formed in the second semiconductor island 154a between the second input electrode 173a and the second output electrode 175a.

The first control electrode 124b connected to the second output electrode 175a, the first input electrode 173b and the ohmic contact 163b connected to the driving voltage line 172, and the first output electrode 175b and the ohmic contact 165b connected to the pixel electrode 191 form a driving thin film transistor Qd along with the first semiconductor island 154b, and the channel of the driving thin film transistor Qd is formed in the first semiconductor island 154b between the first input electrode 173b and the first output electrode 175b.

As above-described, the first semiconductor island 154b is made of microcrystalline silicon, and the second semiconductor island 154a may be made of amorphous silicon. Also, the second semiconductor island 154a may be made of microcrystalline silicon like the first semiconductor island 154b.

The organic light emitting device may emit light toward or away from the substrate 110 to display an image. The opaque pixel electrode 191 and the transparent common electrode 270 are used in the organic light emitting device of a top emission type in which the images are displayed away from the substrate 110, and the transparent pixel electrode 191 and the opaque common electrode 270 are used in the organic light emitting device of a bottom emission type in which the images are displayed downward towards the substrate 110.

According to another exemplary embodiment of the present invention, each pixel PX may include additional transistors to prevent or compensate degradation of the organic light emitting element LD and the driving transistor Qd, as well as one switching transistor Qs and one driving transistor Qd.

In FIG. 11 and FIG. 12, the switching thin film transistor Qs has substantially the same cross-sectional structure as the driving thin film transistor Qd, and the structure of the different portions is slightly changed.

In detail, the data line 171 and the second output electrode 175a are formed with the same layer as the driving voltage line 172 and the first output electrode 175b, the ohmic contacts 163a and 165a are formed with the same layer as the ohmic contacts 163b and 165b, and the buffer members 116a and 116b and the second semiconductor islands 154a and 154b are formed thereon.

A gate insulating layer 140 is formed on the semiconductor islands 154a and 154b, and the gate line 121 is disposed on the gate insulating layer 140 and is covered by the passivation layer 180 having a single-layered structure along with the first control electrode 124b.

In the case of FIG. 11 and FIG. 12, the switching thin film transistor Qs and the driving thin film transistor Qd have the same structure, such that the structure of the organic light emitting device and the manufacturing method thereof are simplified.

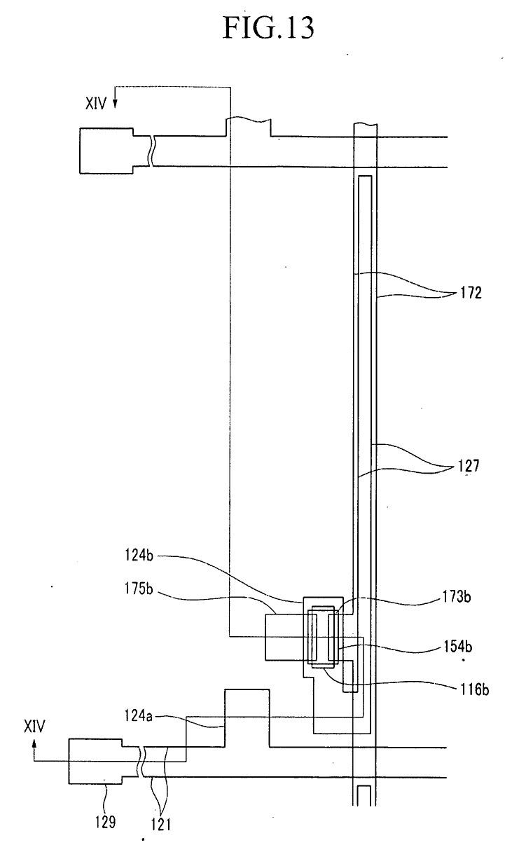

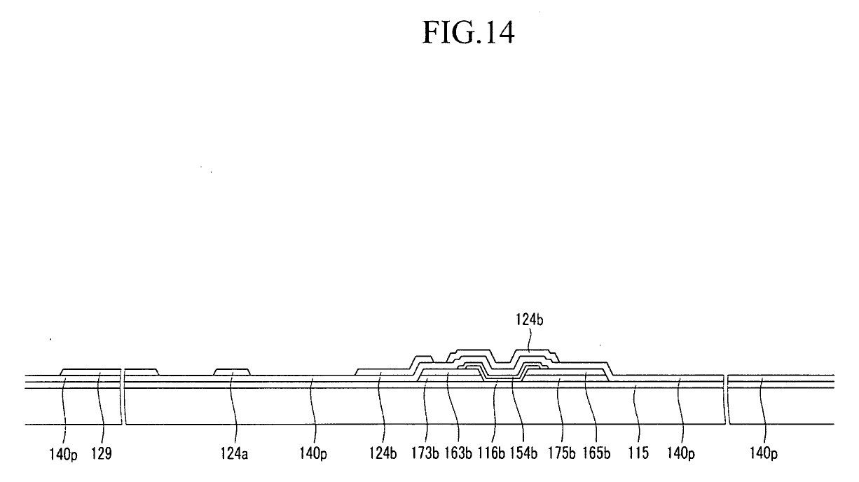

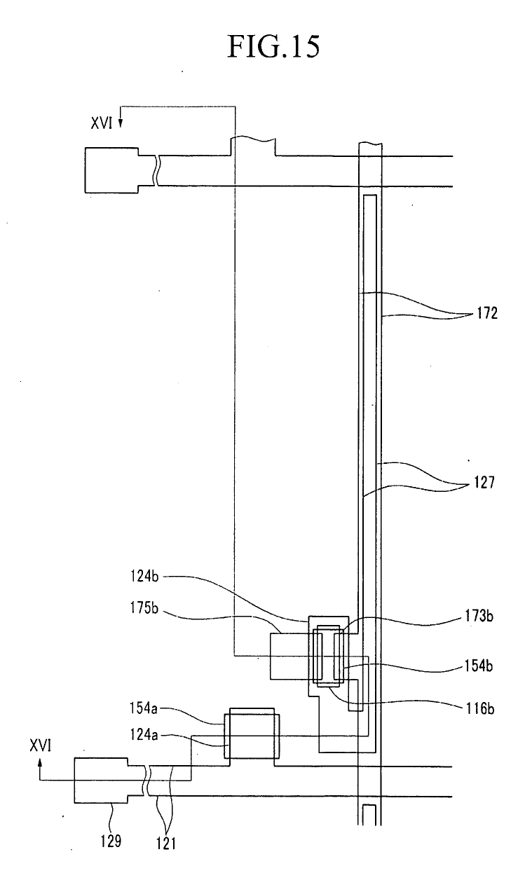

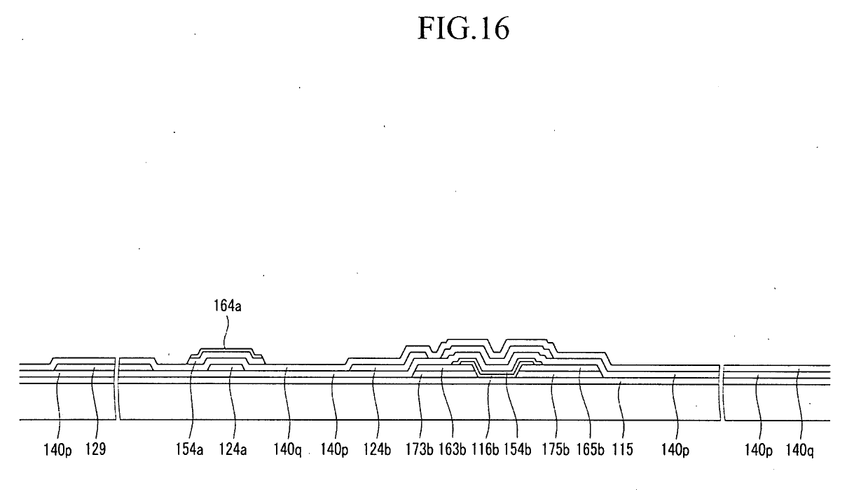

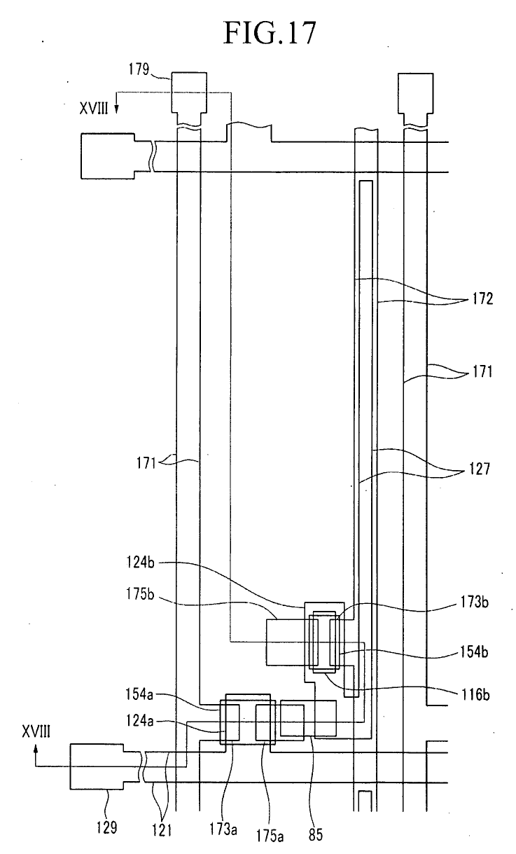

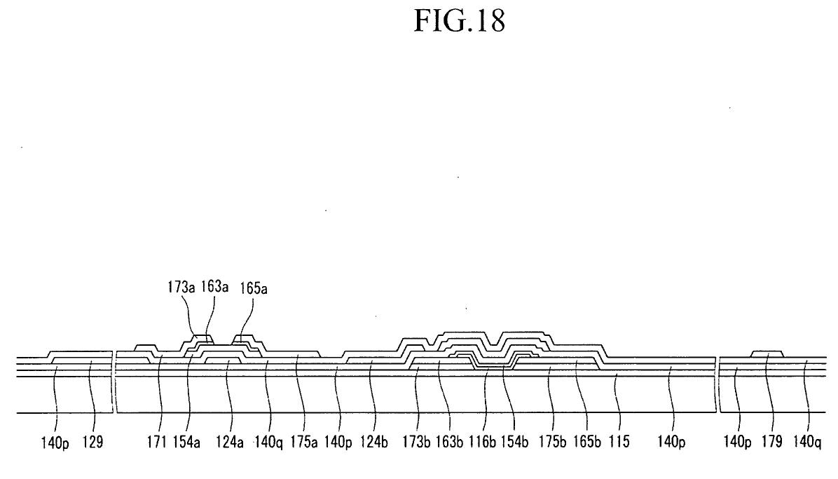

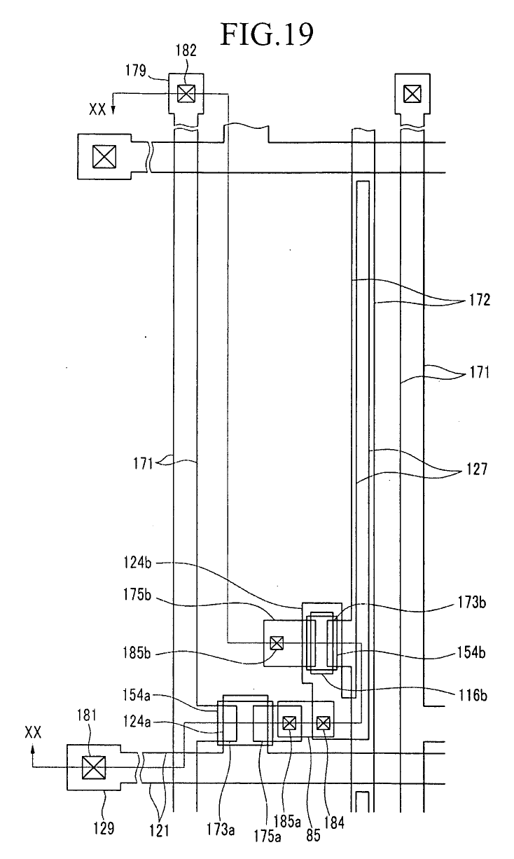

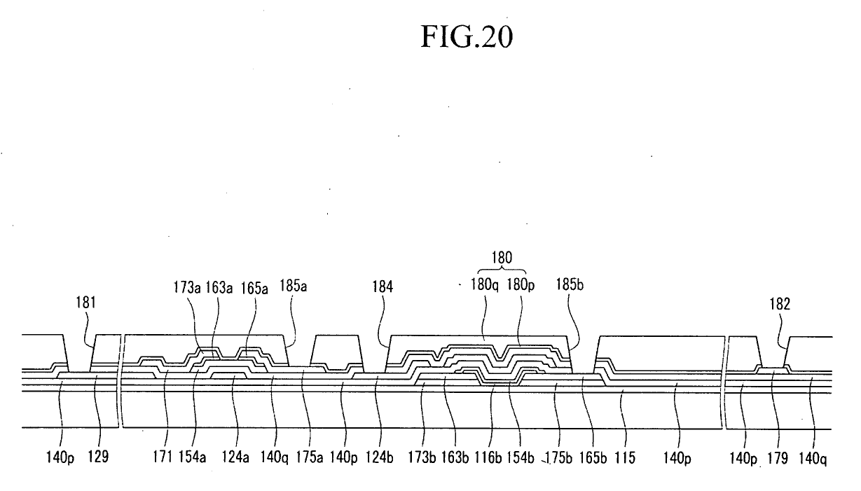

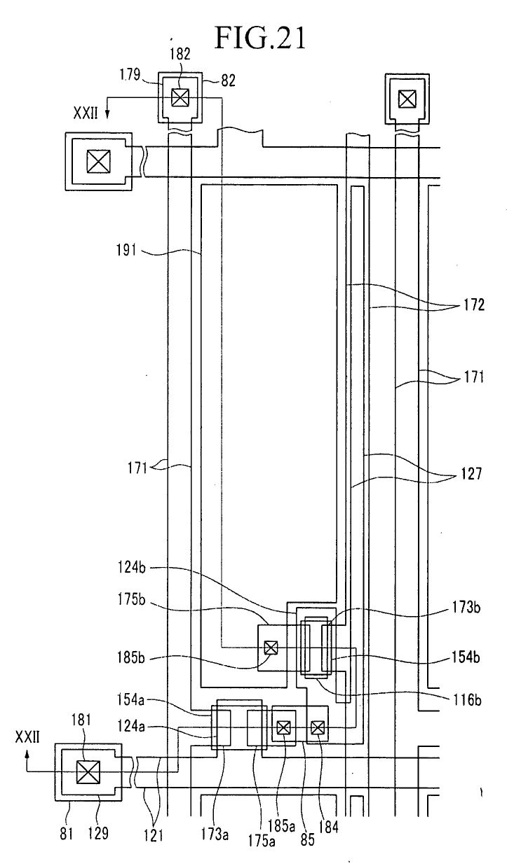

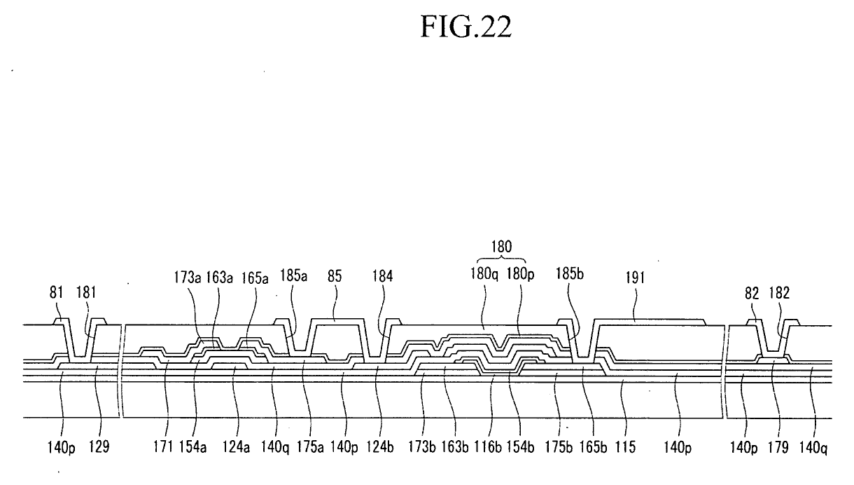

Next, the manufacturing method of the organic light emitting device shown in FIG. 9 and FIG. 10 will be described with reference to FIG. 13, FIG. 14, FIG. 15, FIG. 16, FIG. 17, FIG. 18, FIG. 19, FIG. 20, FIG. 21, and FIG. 22.

FIG. 13, FIG. 15, FIG. 17, FIG. 19, and FIG. 21 are layout views of intermediate steps in the manufacturing method of the organic light emitting device shown in FIG. 9 and FIG. 10 according to an exemplary embodiment of the present invention. FIG. 14 is a cross-sectional view of the organic light emitting device of FIG. 13 taken along line XIV-XIV, FIG. 16 is a cross-sectional view of the organic light emitting device of FIG. 15 taken along line XVI-XVI, FIG. 18 is a cross-sectional view of the organic light emitting device of FIG. 17 taken along line XVIII-XVIII, FIG. 20 is a cross-sectional view of the organic light emitting device of FIG. 19 taken along line XX-XX, and FIG. 22 is a cross-sectional view of the organic light emitting device of FIG. 21 taken along line XXII-XXII.

Referring to FIG. 13 and FIG. 14, a buffer layer 115, a driving voltage line 172, which includes a first input electrode 173b, a first output electrode 175b, ohmic contacts 163b and 165b, a buffer member 116b, and a second semiconductor island 154b are sequentially formed on a substrate 110. The manufacturing method thereof is substantially the same as that of FIG. 2, FIG. 3, and FIG. 4.

Next, a first gate insulating layer 140p is deposited, and then a plurality of gate lines 121 including a plurality of the first control electrodes 124b and second control electrodes 124a and an end portion 129 are formed.

Referring to FIG. 15 and FIG. 16, the second gate insulating layer 140q, an intrinsic amorphous silicon layer, and an impurity amorphous silicon layer are sequentially deposited, and the intrinsic amorphous silicon layer and the impurity amorphous silicon layer are patterned by photolithography to form a plurality of second semiconductor islands 154a and a plurality of impurity semiconductor islands 164a, respectively.

Referring to FIG. 17 and FIG. 18, a metal layer is deposited and patterned by photolithography to form a plurality of data lines 171 including the second input electrodes 173a and an end portion 179, and a plurality of the second output electrodes 175a. Next, the portion of the impurity semiconductor 164a that is not covered by the data line 171 and the second output electrode 175a is removed to form a plurality of ohmic contact islands 163a and 165a, and to expose the portion of the second semiconductor island 154a. Next, O₂ plasma may be used to stabilize the exposed surface of the second semiconductor islands 154a.

Referring to FIG. 19 and FIG. 20, a passivation layer 180 including a lower layer 180p and an upper layer 180q is formed and patterned along with the first and second gate insulating layers 140p and 140q and the ohmic contact 165b to form a plurality of contact holes 181, 182, 184, 185a, and 185b. The contact holes 181, 182, 184, 185a, and 185b respectively expose the end portions 129 of the gate lines 121, the end portions 179 of data lines 171, the first control electrodes 124b, the second output electrodes 175a, and the ohmic contact island 165b.

Referring to FIG. 21 and FIG. 22, a plurality of pixel electrodes 191, a plurality of connecting members 85, and a plurality of contact assistants 81 and 82 are formed on the passivation layer 180.

Finally, referring to FIG. 9 and FIG. 10, a partition 361 including a plurality of openings 365 is formed thereon, and an organic light emitting member 370 and a common electrode 270 are formed.

The present invention may be applied to an organic light emitting device having various structures.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor, comprising:
a first electrode arranged on a substrate;
a second electrode arranged on the substrate and separated from the first electrode;
a first ohmic contact arranged on an upper surface of the first electrode;
a second ohmic contact arranged on an upper surface of the second electrode;
a first buffer member covering a lateral surface of the first electrode and a lateral surface of the second electrode;
a semiconductor member contacted with an upper surface of the first buffer member, the first ohmic contact, and the second ohmic contact;
an insulating layer arranged on the semiconductor member; and
a third electrode arranged on the insulating layer and on the semiconductor member.

2. The thin film transistor of claim 1, wherein
the first buffer member comprises silicon oxide or silicon nitride.

3. The thin film transistor of claim 2, wherein
the first buffer member covers a portion of the upper surface of the first electrode and the second electrode.

4. The thin film transistor of claim 3, wherein
the first buffer member covers the entire portion of the substrate located between the first electrode and the second electrode.

5. The thin film transistor of claim 4, wherein
the semiconductor member comprises microcrystalline silicon.

6. The thin film transistor of claim 5, wherein
a grain diameter of the microcrystalline silicon is less than 10 μm.

7. The thin film transistor of claim 6, wherein
the first ohmic contact and the second ohmic contact comprise polysilicon further comprising an impurity.

8. The thin film transistor of claim 7, wherein
a plane shape of the first electrode is the same as a plane shape of the first ohmic contact, and a plane shape of the second electrode is the same as a plane shape of the second ohmic contact.

9. The thin film transistor of claim 8, further comprising
a second buffer member arranged on the substrate, wherein the first electrode, the second electrode, and the first buffer member are arranged on the second buffer member.

10. A method for manufacturing a thin film transistor, comprising:
forming a first electrode and a second electrode on a substrate;
respectively forming a first ohmic contact and second ohmic contact on an upper surface of the first electrode and an upper surface of the second electrode;
forming a buffer member on the first ohmic contact, the second ohmic contact, and the substrate;
forming a semiconductor member on the buffer member, the first ohmic contact, and the second ohmic contact;
forming an insulating layer on the semiconductor member; and
forming a third electrode on the insulating layer.

11. The method of claim 10, wherein
the semiconductor member comprises microcrystalline silicon.

12. The method of claim 11, wherein
the first ohmic contact and the second ohmic contact comprise polysilicon further comprising an impurity.

13. The method of claim 10, wherein
the first ohmic contact, the second ohmic contact, the first electrode, and the second electrode are formed through one photolithography step.

14. The method of claim 10, further comprising
before forming the first electrode and the second electrode, forming a buffer layer on the substrate.

15. An organic light emitting device, comprising:
an organic light emitting element to emit light according to a driving current;
a driving transistor connected to the organic light emitting element to flow the driving current according to a data signal, and
a switching transistor to transmit the data signal to the driving transistor,
wherein the driving transistor comprises:
a first electrode arranged on a substrate;
a second electrode arranged on the substrate and separated from the first electrode;
a first ohmic contact arranged on an upper surface of the first electrode;
a second ohmic contact arranged on an upper surface of the second electrode;
a first buffer member covering a lateral surface of the first electrode and a lateral surface of the second electrode;
a semiconductor member contacted with an upper surface of the first buffer member, the first ohmic contact, and the second ohmic contact;
an insulating layer arranged on the semiconductor member; and
a third electrode arranged on the insulating layer and on the semiconductor member.
